(19) United States
(12) Patent Application Publication
(10) Pub. No.: US 2008/0157830 A1
(43) Pub. Date: Jul. 3, 2008

(54) TRIANGLE OSCILLATOR AND PULSE WIDTH MODULATOR

(75) Inventor: Tomohiro Kume, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/950,443

(22) Filed: Dec. 5, 2007

(30) Foreign Application Priority Data
Dec. 28, 2006 (JP) 2006-353568

(51) Int. Cl. H03K 4/06; H03K 7/08; H03K 3/0233; H03B 1/00

(52) U.S. Cl. 327/110; 331/153; 327/140; 327/291

(57) ABSTRACT

The present invention relates to an oscillator outputting two triangle waves having the same amplitude and whose phases are inverted; and a pulse width modulator using the oscillator. A capacitor 3 is charged or discharged by a charge pump circuit 2 controlled by a Schmitt circuit 1, and a voltage integrated by a two-output differential amplification circuit 6 is positively fed back to the input of the Schmitt circuit 1 to output two triangle waves having the same amplitude and whose phases are inverted. Since the output stage is composed of a differential amplification circuit, the circuit has low output impedance and is protected from wiring capacity and connected input capacity, and since integral operation is caused to be performed by the differential amplification circuit, the distortion in the waveform of the triangle waves can be prevented.

### FIELD OF THE INVENTION

The present invention relates to an oscillator circuit outputting two triangle waves having the same amplitude but whose phases are inverted, and a pulse width modulator (PWM) circuit using such an oscillator circuit.

### BACKGROUND OF THE INVENTION

Heretofore, when two triangle waves having the same amplitude but whose phases are inverted are generated, triangle waves generated by a triangle oscillator are inverted using an amplifier. FIGS. 6 and 7 show a first conventional embodiment and a second conventional embodiment, respectively.

In the first conventional embodiment shown in FIG. 6, a triangle wave formed by a triangle oscillator 100 and an output voltage of a differential amplification circuit 101 are divided by two resistors R1, R1 having the same resistance, and the resistance-divided midpoint voltage is fed back to the inverting input terminal (−) of the differential amplification circuit 101, to supply set reference voltage to the non-inverting input terminal (+) of the differential amplification circuit to be virtually grounded, and invert the waveform of the triangle wave centering around the reference voltage.

In the second conventional embodiment shown in FIG. 7, a complete differential amplification circuit 102 described in an article by P. R. Gray et al. listed below is negatively fed back via a resistor R3 to generate two outputs instead of using the differential amplification circuit 101 and divided resistors R1 and R1 in the first conventional embodiment shown in FIG. 6. The two outputs are a gain-multiplied voltage determined from the resistance ratio, and a voltage generated by inverting such a voltage. Incidentally, in FIG. 7, a common feedback circuit for determining the in-phase operation point voltage is omitted.

P. R. Gray, P. J. Hurst, S. H. Lewis, R. G. Meyer, “ANALYSTS AND DESIGN OF ANALOG INTEGRATED CIRCUITS Fourth Edition”, John Wiley & Sons, Inc., 2001, pp. 808-809, 823-830, and 839

An invention to control discharge current to two capacitors by in-phase feedback not by inverting amplification to simultaneously produce two triangle waves is disclosed in Japanese Patent Laid-Open No. 2006-50310.

### DISCLOSURE OF THE INVENTION

In the first conventional embodiment, however, when oscillating frequency exceeds several hundred kilohertz, the waveform of triangle waves in an output signal S4 from an output terminal 4 is distorted as compared with an output signal S5 from an output terminal 5 as shown in FIG. 8A, and does not become triangle due to frequency response and slew rate of an amplifier. This results in unfavorable characteristics that the modulation factor in a pulse width modulator (PWM) circuit where a triangle wave is a comparison signal (=duty/input voltage, or =average output voltage/input voltage=output amplitude×duty/input voltage) is out of a constant modulation factor in the vicinities of output duties of 0 and 100%, and has non-linearity. In a dual-phase PWM circuit, such as a dual-phase switching regulator and a bridge driver for driving an actuator, sufficient accuracy cannot be secured. Furthermore, the linearity accuracy of triangle waves has a disadvantage in that the fluctuation of the offset and gain of an amplifier is multiplied in addition to the input offset of an oscillator itself. To reduce these fluctuations, the sizes of the amplifier, resistors and the like must be increased or adjustment and the like are required; however, the costs of the circuit are also elevated.

In the second conventional embodiment, since the output impedance is high, the transmission of harmonics of a triangle waveform is impeded by the parasitic capacitance of wirings to the PWM comparator or the input capacitance of the differential input stage of the PWM comparator or distort both the output signals S4 and S5 as shown in FIG. 8B. For the second conventional embodiment, although the phenomenon of waveform distortion can be avoided by inserting a high-speed buffer in the next stage of the output, a problem of increase in the number of elements and the occurrence of offset between two outputs due to the fluctuation of elements in the buffer is newly caused.

To solve the problems described above, it is an object of the present invention to provide a highly accurate oscillator having a low-impedance output that operates at not less than several hundred kilohertz, and generating two triangle waves having the same amplitude and whose phases are inverted.

A triangle oscillator according to claim 1 of the present invention includes a Schmitt circuit having two different threshold voltages for an input, exhibiting a first output state when an input voltage elevates and reaches a first threshold voltage, and exhibiting a second output state when the input voltage lowers and reaches a second threshold voltage; a charge pump circuit whose input is connected to the output of the Schmitt circuit, whose output current has a constant value, and having output that switches two directions of pulling in and flowing out; a capacitor one of whose ends is connected to the output of the charge pump circuit; and a two-output differential amplification circuit whose first input terminal is connected to the connecting point of the output of the charge pump circuit with the capacitor, whose second input terminal is connected to a reference voltage, and whose first output terminal is connected to the other end of the capacitor, outputting a voltage formed by amplifying voltage difference between the first input terminal and the second input terminal as voltage difference between the first output terminal and the second output terminal, and connecting one of the first output terminal or the second output terminal with the input of the Schmitt circuit, wherein the output current of the charge pump circuit is charged or discharged in a first current direction when the Schmitt circuit is in the first output state, the output current of the charge pump circuit is charged or discharged in a second current direction when the Schmitt circuit is in the second output state, thereby to positively feed back the voltage or the inverted voltage integrated by the capacitor and the two-output differential amplification circuit, to generate triangle waves in the first output terminal of the two-output differential amplification circuit, and to generate phase-inverted triangle waves in the second output terminal.

A triangle oscillator according to claim 2 of the present invention is constituted so that the Schmitt circuit in claim 1 is composed of two comparators and an RS flip flop; one input of the first comparator among the comparators is connected to one input of the second comparator to be the input of the Schmitt circuit; different constant voltages providing a threshold are applied to the other input of the first comparator and the other input of the second comparator, respectively; the output of the first comparator is connected to the set input of the RS flip flop; the output of the second comparator is connected to the reset input of the RS flip flop; and the output of the RS flip flop is applied to the input of the charge pump circuit to control the charge pump circuit so as to switch the first current direction and the second current direction of the output current.

A triangle oscillator according to claim 3 of the present invention is constituted so that the Schmitt circuit in claim 1 is composed of a hysteresis comparator having high and low threshold vantage values, and the output of the hysteresis comparator is applied to the input of the charge pump circuit, to control the first current direction and the second current direction of the output current of the charge pump circuit to be switched.

A pulse width modulator according to claim 4 of the present invention is constituted so that the two outputs of the triangle oscillator according to claim 1 are connected to one input terminal of each of the two comparators, and the same input voltage is applied to the other terminals to generate two pulse width modulated pulse outputs at outputs of the two comparators.

A actuator driver according to claim 5 of the present invention applies the two pulse outputs of the pulse width modulator according to claim 4 to the input of the respective pre-drivers, chop-controls each arm of an H-bridge driver using each pre-driver, and drives an actuator, which is the load of the H-bridge driver.

An output stage of the present invention is composed of a differential amplification circuit, and low-output impedance can be achieved. In addition, since the differential amplification circuit is integrally operated, the waveform of the triangle wave can be faithfully outputted without distortion.

### BRIEF DESCRIPTION OF THE DRAWINGS

FIG. 1 is a block diagram of an actuator driving device including a triangle oscillator according to the present invention;

FIG. 2 is a detailed block diagram of the triangle oscillator according to an embodiment of the present invention;

FIG. 3 is a block diagram of a charge pump circuit according to the embodiment of the present invention;

FIG. 4 is a detailed block diagram of a two-output differential amplification circuit according to the embodiment of the present invention;

FIG. 5 is a voltage and current waveform diagram of the triangle oscillator according to the embodiment of the present invention;

FIG. 6 is a block diagram of a triangle oscillator according to a first conventional embodiment;

FIG. 7 is a block diagram of a triangle oscillator according to a second conventional embodiment;

FIG. 8A is a voltage and current waveform diagram of the triangle oscillator according to the first conventional embodiment; and

FIG. 8B is a voltage and current waveform diagram of the triangle oscillator according to the second conventional embodiment.

### DESCRIPTION OF THE EMBODIMENT(S)

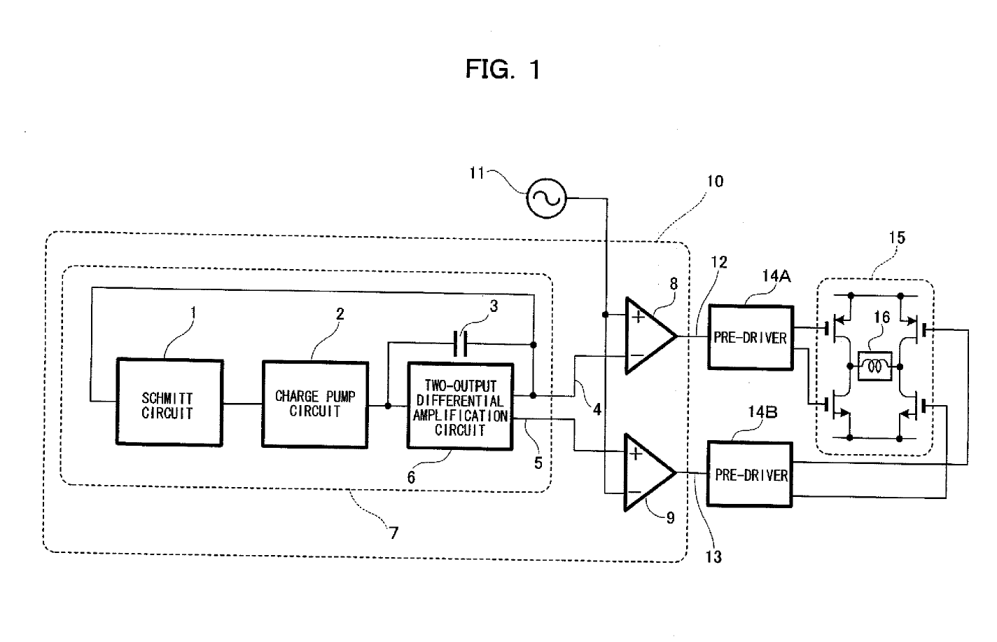

The present invention will be described referring to FIGS. 1 to 5 showing an embodiment of the present invention.

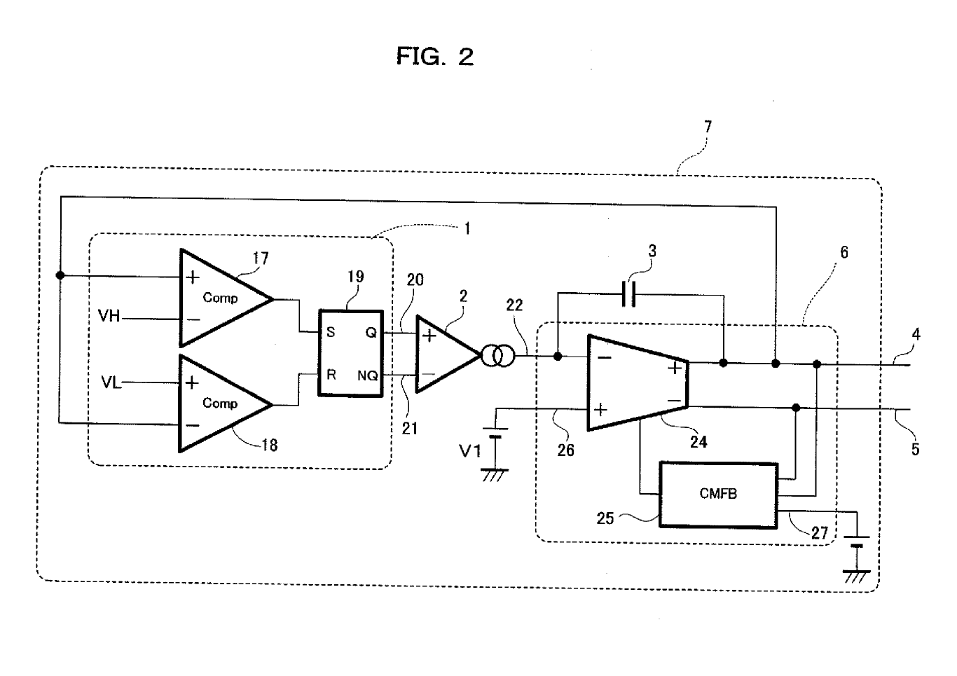

FIG. 1 is a block diagram showing an actuator driving device using a pulse width modulator according to the embodiment of the present invention, and FIG. 2 shows the triangle oscillator shown in FIG. 1.

In FIG. 1, a triangle oscillator 7 includes a Schmitt circuit 1 having two different threshold voltages for an input, exhibiting a first output state when an input voltage elevates and reaches a first threshold voltage, and exhibiting a second output state when an input voltage lowers and reaches a second threshold voltage; a charge pump circuit 2 whose input is connected to the output of the Schmitt circuit 1, whose output current has a constant value, and having output that switches two directions of pulling in and flowing out; a capacitor 3 one of whose ends is connected to the output of the charge pump circuit 2; and a two-output differential amplification circuit 6 whose first input terminal is connected to the connecting point of the output of the charge pump circuit 2 with the capacitor 3, whose second input terminal is connected to a second reference voltage, and whose first output terminal 4 is connected to the input of the Schmitt circuit 1 with the other end of the capacitor 3, outputting a voltage formed by amplifying voltage difference between the first input terminal and the second input terminal as voltage difference between the first output terminal 4 and the second output terminal 5. The two-output differential amplification circuit 6 achieves an effect to output two triangle waves at low impedance.

The output current of the charge pump circuit 2 is charged or discharged in a first current direction when the Schmitt circuit 1 is in the first output state, the output current of the charge pump circuit 2 is charged or discharged in a second current direction when the Schmitt circuit 1 is in the second output state, thereby to positively feed back the voltage integrated by the capacitor 3 and the two-output differential amplification circuit 6 by the connection described above, to generate triangle waves in the first output terminal 4 of the two-output differential amplification circuit 6. At the same time, inverted triangle waves of the first output terminal 4 is outputted in the second output terminal 5 by the two-output differential amplification circuit 6. By such an integration circuit, since the phase margin of the two-output differential amplification circuit 6 is corrected by the capacitor 3, and the phase compensating capacitor in the two-output differential amplification circuit 6 is not required, or a sufficient phase margin is obtained by an extremely small quantity of several picofarads or less, an effect that the distortion of waveform due to transient response is difficult to occur even if the oscillation frequency is elevated can be obtained.

The accuracy of oscillation amplitudes depends only on the accuracy of the threshold of the Schmitt circuit 1, and does not depend on the input voltage offset of the two-output differential amplification circuit 6. Therefore, since the input stage that composes the two-output differential amplification circuit 6 may have offset, a simple configuration can be taken.

By connecting the first output terminal 4 and the second output terminal 5 of the triangle oscillator 7 shown in FIG. 1 to an input of each of two comparators 8 and 9, and applying the same input signal 11 to the other input terminals of the two comparators, dual-phase PWM signals 12 and 13 are outputted from the comparators 8 and 9, respectively. Since the waveform of inputted triangle waves is not distorted in frequencies as high as several hundred kilohertz or more, a PWM circuit having favorable linearity in the modulation factor to input voltages in the vicinity of 0% and 100% duties can be obtained.

The two PWM signals 12 and 13 generated from the PWM circuit 10 are applied to pre-drivers 14A and 14B, respectively, the pre-drivers 14A and 14B chop-control each arm of the H-bridge driver 15, and drive the actuator 16. By such a configuration, an effect to generate duty ratio accurately proportional to the input signal 11 on the basis of the excellent characteristics of the triangle oscillator 7 can be obtained.

The Schmitt circuit 1 can be composed of two comparators 17 and 18 and an RS flip-flop 19 as shown in FIG. 2. In another embodiment, the Schmitt circuit 1 can be composed of a hysteresis comparator.

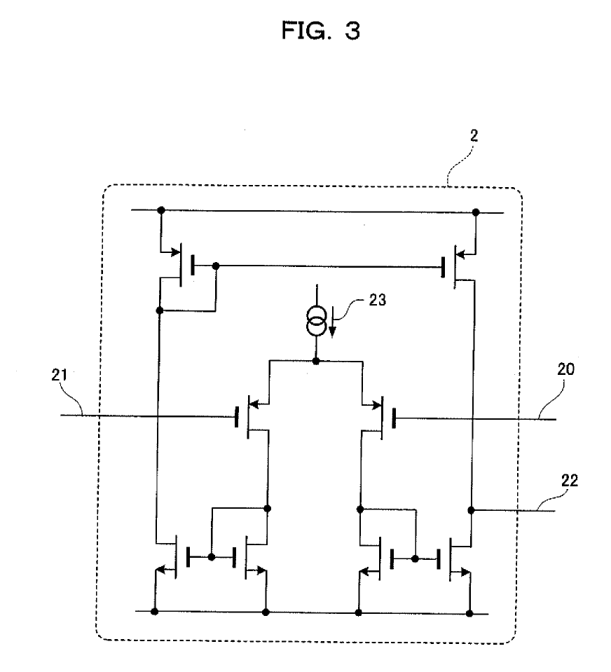

FIG. 3 is a circuit diagram of an example of the charge pump circuit 2; and FIG. 4 is a circuit diagram of an example of the two-output differential amplification circuit 6.

Referring to FIG. 2, the Schmitt circuit 1 is a circuit to take a first output state (output 20 of the RS flip-flop 19 is Q=H level, and output 21 of the ES flip-flop 19 is NQ=L level) when the input voltage elevates and crosses the first threshold voltage (threshold voltage VH of the comparator 17); and take a second output state (the output 20 of the RS flip-flop 19 is Q=L level, and the output 21 of the RS flip-flop 19 is NO=H level) when the input voltage lowers and crosses the second threshold voltage (threshold voltage VL of the comparator 18). The first threshold voltage and the second threshold voltage are set to have a relationship of (first threshold voltage VH)>(second threshold voltage VL).

The charge pump circuit 2 pulls in and flows out a constant current, and the direction of the current is switched corresponding to the first and second output states of the Schmitt circuit 1. Specifically, when the Schmitt circuit 1 is in the first output state, the output current in the charge pump circuit 2 flows out in the first current direction to charge the capacitor 3; on the contrary, when the Schmitt circuit 1 is in the second output state, the output current in the charge pump circuit 2 is drawn in the second current direction to discharge the capacitor 3.

FIG. 3 shows an illustrative example of the charge pump circuit 2.

This utilizes an OTA (operational transconductance amplifier) described by P. R. Gray, et al. By connecting output Q20 and inverted output NQ21 of the RS flip-flop 19 shown in FIG. 2 to both the differential input terminals, respectively, in the first output state of the Schmitt circuit 1, current of the multiple of a set mirror ratio of tail current 23 is drawn into the output 22; and in the second output state of the Schmitt circuit 1, current of the multiple of a set mirror ratio of the tail current 23 is flowed into the output 22.

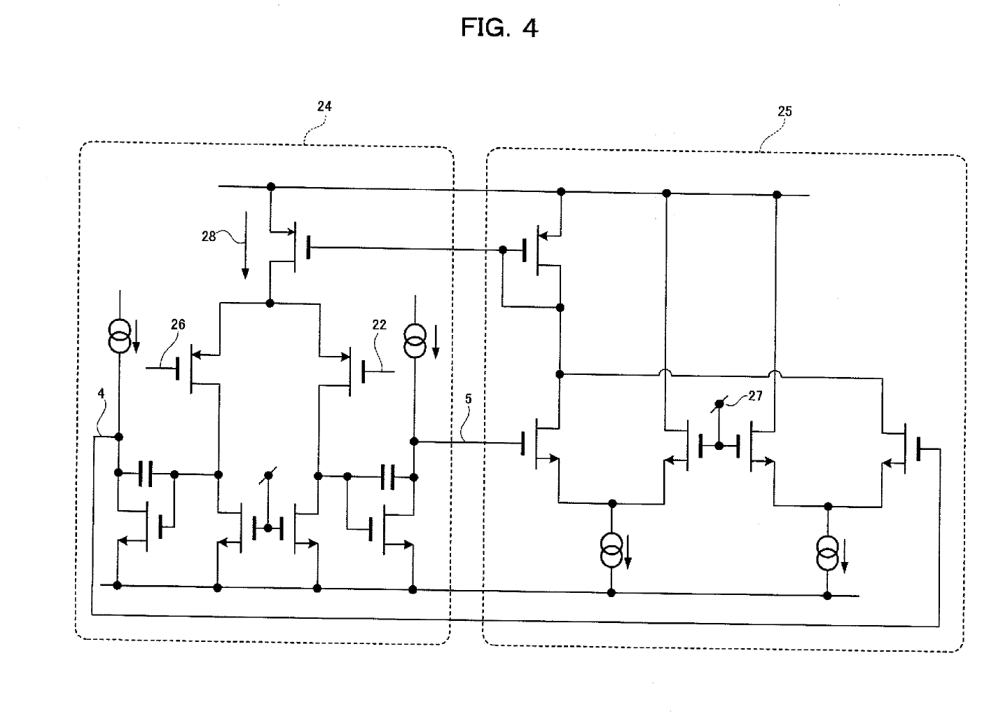

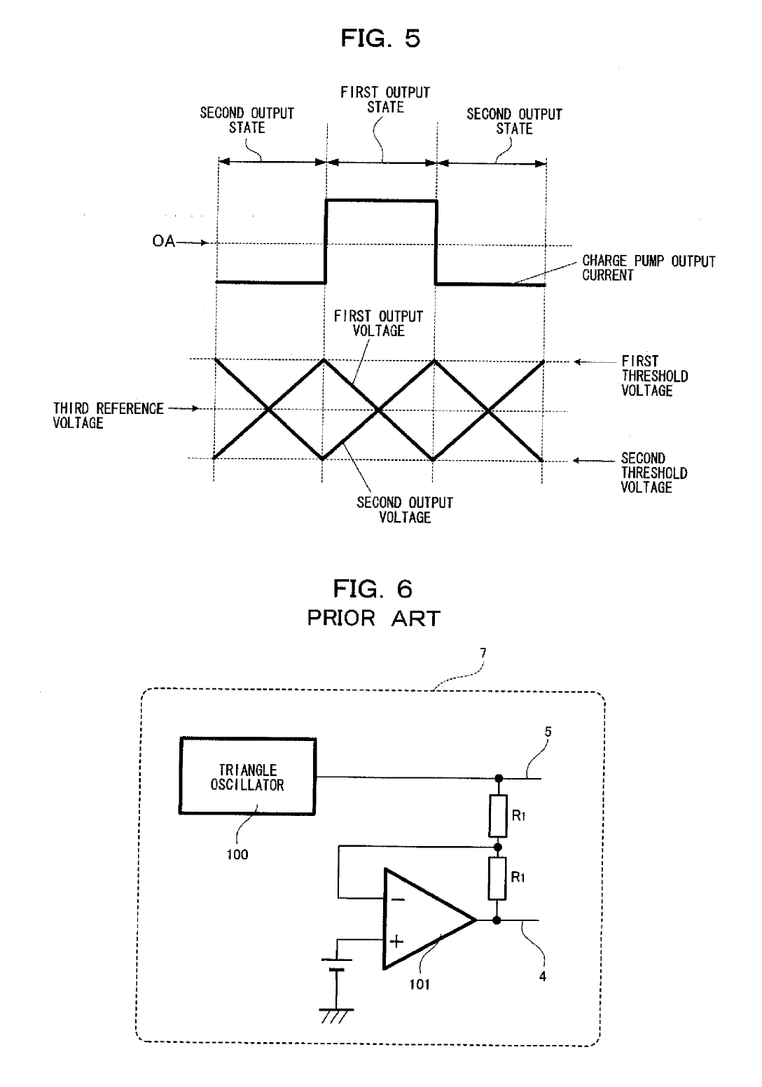

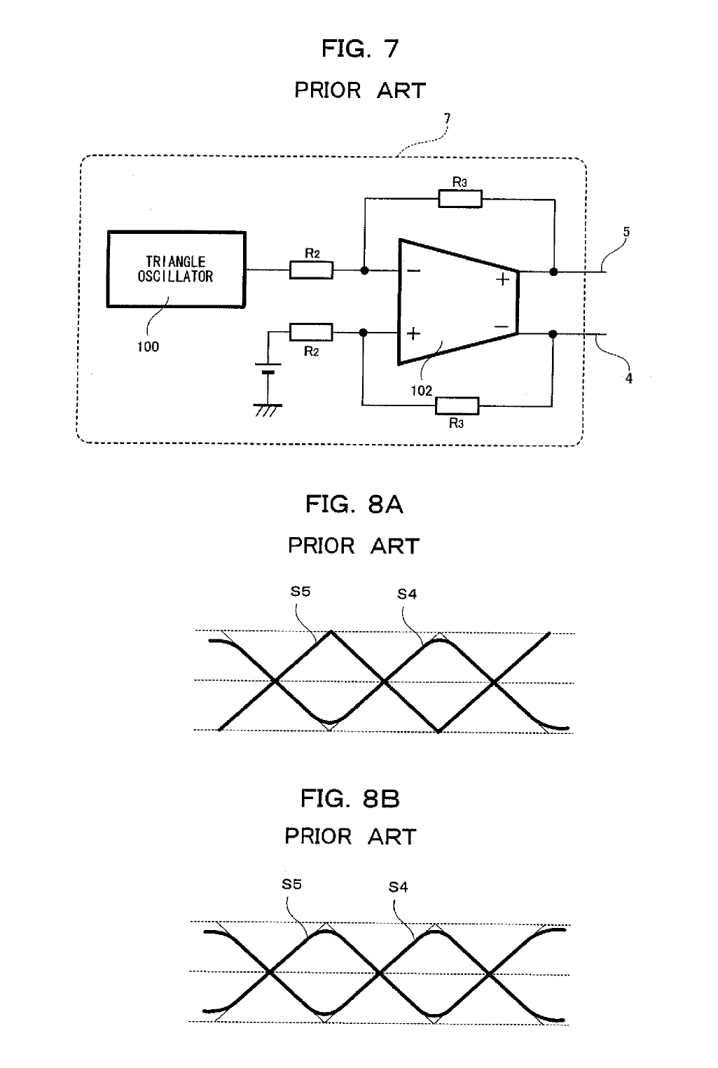

The two-output differential amplification circuit 6 is composed of a complete differential amplification circuit described by P. R. Gray, et al., and consists of an operational amplifier 24 and a common-mode feedback circuit 25. One of the outputs is negatively fed back to one of the inputs by the capacitor 3, and the voltage is substantially matched with the potential of first reference voltage 26 by virtual grounding. As shown in the waveforms in FIG. 5, in the first output terminal 4 of the two-output differential amplification circuit 6, which is the other end of the capacitor 3, the voltage lowers in a constant gradient during charging (first output state), and the voltage elevates in a constant gradient during discharging (second output state) by integral operation. The first output terminal 4 is connected to the input of the Schmitt circuit 1, and switches the output states by the threshold voltage of the Schmitt circuit 1 to generate triangle waves shown in FIG. 5 at the first output terminal 4 and the second output terminal 5 on reaching the third reference voltage.

Since the second output terminal 5 is subjected to negative feedback by the common-mode feedback circuit 25 of the two-output differential amplification circuit 6 so that the intermediate voltage of the voltage of the first output terminal 4 and the second output terminal 5 matches the second reference voltage 27, a triangle wave having an inverted waveform of the first output terminal 4; specifically, a triangle wave having the same amplitude with the phase inverted is generated with respect to the second reference voltage.

In the Schmitt circuit 1, the two comparators 17 and 18, and RS flip-flop 19 shown in FIG. 2 may be substituted by a hysteresis comparator. Although not shown in the drawing, the same effect can be obtained by using the two threshold voltages of the hysteresis comparator as the two threshold voltages described above.

Although the input of the Schmitt circuit 1 is positively fed back by connecting to the first output terminal 4 of the output differential amplification circuit 6 to which the capacitor 3 is connected, the input of the Schmitt circuit 1 may be connected to the second output terminal 5 to which the capacitor 3 is not connected. In this case, the output state of the Schmitt circuit 1 is switched to the current-flow direction of the charge pump circuit 2 so as to be positively fed back. Specifically, the polarities of the output Q20 and the output NQ21 of the RS flip-flop 19 can be replaced.

Although it has been described that the pulled in and flowed out currents of the charge pump circuit 2 have the same quantity but the directions thereof are inverted, by optionally setting the current ratios of the both currents, any triangle waves and saw-tooth waves can be generated. In the charge pump circuit in FIG. 3, by changing the mirror ratios of the upper and lower current mirrors, optional triangle waves and saw-tooth waves can be generated.

The circuit shown in FIG. 4 is an embodiment of the two-output differential amplifier circuit 6 and cited from the above-described document of P. R. Gray, et al. The circuit is composed of an operational amplifier 24 and a common-mode feedback circuit 25, and the operational amplifier 24 amplifies and outputs the voltage difference between input terminals 22 and 26 as the voltage difference between the two output terminals 4 and 5. The common-mode feedback circuit 25 controls tail current 28 of the operational amplifier 24 so that the intermediate voltage of the voltages of the two output terminals 4 and 5 is matched to the second reference voltage 27.

The actuator driving circuit having a configuration connecting and chopping the H-bridge driver 15 that drives the actuator 16 in FIG. 1 to each of two outputs 12 and 13 of the PWM circuit 10 via the pre-drivers 14 constitutes a high-accuracy actuator driving circuit having the modulation factor with favorable linearity.

The PWM circuit 10 in the present embodiment can also be used in optional H-bridge driving circuits other than the actuator driving circuit.

The triangle oscillator and pulse width modulator according to the present invention have an effect of preventing the distortion of waveforms even at frequencies of several hundred kilohertz or higher, and are useful as a two-output triangle oscillator and pulse width modulator controlled by two PWM frequencies of several hundred kilohertz or higher, such as a PWM controlled H-bridge driving device including audio amplifiers and actuator driving devices.

What is claimed is:

1. A triangle oscillator comprising:
a Schmitt circuit having two different threshold voltages for an input, exhibiting a first output state when an input voltage elevates and reaches a first threshold voltage, and exhibiting a second output state when the input voltage lowers and reaches a second threshold voltage;
a charge pump circuit whose input is connected to the output of the Schmitt circuit, whose output current has a constant value, and having output that switches two directions of pulling in and flowing out;
a capacitor one of whose ends is connected to the output of the charge pump circuit; and
a two-output differential amplification circuit whose first input terminal is connected to the connecting point of the output of the charge pump circuit with the capacitor, whose second input terminal is connected to a reference voltage, and whose first output terminal is connected to the other end of the capacitor, outputting a voltage formed by amplifying voltage difference between the first input terminal and the second input terminal as voltage difference between the first output terminal and the second output terminal, and connecting one of the first output terminal or the second output terminal with the input of the Schmitt circuit; wherein
the output current of the charge pump circuit is charged or discharged in a first current direction when the Schmitt circuit is in the first output state, the output current of the charge pump circuit is charged or discharged in a second current direction when the Schmitt circuit is in the second output state, thereby to positively feed back the voltage or the inverted voltage integrated by the capacitor and the two-output differential amplification circuit to the Schmitt circuit, to generate triangle waves at the first output terminal of the two-output differential amplification circuit, and to generate phase-inverted triangle waves at the second output terminal.

2. The triangle oscillator according to claim 1, wherein the Schmitt circuit is composed of two comparators and an RS flip flop; one input of the first comparator among the comparators is connected to one input of the second comparator to be the input of the Schmitt circuit; different constant voltages providing a threshold are applied to the other input of the first comparator and the other input of the second comparator, respectively; the output of the first comparator is connected to the set input of the RS flip flop; the output of the second comparator is connected to the reset input of the RS flip flop; and the output of the RS flip flop is applied to the input of the charge pump circuit to control the charge pump circuit so as to switch the first current direction and the second current direction of the output current.

3. The triangle oscillator according to claim 1, wherein the Schmitt circuit is composed of a hysteresis comparator having high and low threshold vantage values, and the output of a hysteresis comparator is applied to the input of the charge pump circuit, to control the first current direction and the second current direction of the output current of the charge pump circuit to be switched.

4. A pulse width modulator constituted so that the two outputs of the triangle oscillator according to claim 1 are connected to one input terminal of each of two comparators, and the same input voltage is applied to the other terminals to generate two pulse width modulated pulse outputs at outputs of the two comparators.

5. An actuator driver comprising a pulse width modulator constituted so that two outputs of a triangle oscillator are connected to one input terminal of each of two comparators, and the same input voltage is applied to the other terminals to generate two pulse width modulated pulse outputs at outputs of the two comparators; first and second pre-drivers whose inputs are connected to the two pulse outputs of the pulse width modulator, respectively; and an H bridge driver whose each arm is chop controlled by the output of the first and second pre-drivers; wherein
the triangle oscillator comprises:
a Schmitt circuit having two different threshold voltages for an input, exhibiting a first output state when an input voltage elevates and reaches a first threshold voltage, and exhibiting a second output state when the input voltage lowers and reaches a second threshold voltage;
a charge pump circuit whose input is connected to the output of the Schmitt circuit, whose output current has a constant value, and having output that switches two directions of pulling in and flowing out;
a capacitor one of whose ends is connected to the output of the charge pump circuit; and
a two-output differential amplification circuit whose first input terminal is connected to the connecting point of the output of the charge pump circuit and the capacitor, whose second input terminal is connected to a reference voltage, and whose first output terminal is connected to the other end of the capacitor, outputting a voltage formed by amplifying voltage difference between the first input terminal and the second input terminal as voltage difference between the first output terminal and the second output terminal, and connecting one of the first output terminal or the second output terminal with the input of the Schmitt circuit; wherein
the output current of the charge pump circuit is charged or discharged in a first current direction when the Schmitt circuit is in the first output state, the output current of the charge pump circuit is charged or discharged in a second current direction when the Schmitt circuit is in the second output state, thereby to positively feed back the voltage or the inverted voltage integrated by the capacitor and the two-output differential amplification circuit, to generate triangle waves at the first output terminal of the two-output differential amplification circuit, and to generate phase-inverted triangle waves at the second output terminal; and
constituted so as to drive an actuator, which is the load of the H-bridge driver.
